(19) United States
(12) Patent Application Publication
(10) Pub. No.: US 2017/0278888 A1
(43) Pub. Date: Sep. 28, 2017

(54) IMAGE SENSOR WITH INNER LIGHT-CONDENSING SCHEME

(71) Applicants: SK hynix Inc., Gyeonggi-do (KR); POSTECH ACADEMY-INDUSTRY FOUNDATION, Gyeongsangbuk-do (KR)

(72) Inventors: Hae Wook HAN, Gyeongsangbuk-do (KR); Young Woong DO, Daegu-si (KR)

(21) Appl. No.: 15/187,213

(22) Filed: Jun. 20, 2016

(30) Foreign Application Priority Data
Mar. 24, 2016 (KR) 10-2016-0035069

(51) Int. Cl. H01L 27/146

(52) U.S. Cl. CPC H01L 27/14627; H01L 27/1462; H01L 27/14621; H01L 27/14645

(57) ABSTRACT

An image sensor may include: a photoelectric conversion layer; an anti-reflection layer formed over the photoelectric conversion layer so as to minimize reflectance of light; a guide layer formed over the anti-reflection layer, and suitable for guiding the light to the photoelectric conversion layer; and a first condensing layer buried at the inner top of the guide layer, and suitable for condensing incident light.

### CROSS-REFERENCE TO RELATED APPLICATIONS

The present application claims priority under 35 U.S.C. §119(a) to Korean Patent Application No. 10-2016-0035069, filed on Mar. 24, 2016, which is incorporated herein by reference in its entirety.

### BACKGROUND

1. Field

Exemplary embodiments of the present invention relate generally to image sensor technology and, more particularly, to a technology for improving the sensitivity of an image sensor.

2. Description of the Related Art

Generally, an image sensor converts an optical image into an electrical signal. Image sensors are used widely in various electronic devices in different fields, such as, for example, digital cameras, camcorders, mobile terminals, security cameras, medical micro cameras and so forth.

Image sensors are broadly categorized into CCD (Charge Coupled Device) image sensors and CMOS (Complementary Metal Oxide Semiconductor) image sensors. The CMOS image sensors have high integration density and low power consumption, and may be implemented as an integrated circuit.

An image sensor may typically include a pixel array having a plurality of pixels for sensing an optical image. Each pixel of the pixel array may typically include a microlens for focusing incident light and a photo diode for converting incident light into an electrical signal. The pixel may store a photo charge corresponding to incident light through the photo diode, and output a pixel signal based on the stored photo charge.

Recently, with the development of a semiconductor technology, the size of pixels has been gradually reduced. According to the size reduction, the curvature radius of the microlens must be controlled in order to improve the light focusing efficiency.

However, the microlens of a conventional image sensor has a curvature radius that is difficult to control due to process limitations. As a result, the light condensing efficiency is inevitably degraded when the pixel size is reduced. Thus, there is a need for new technology capable of increasing the light condensing efficiency of microlenses.

Korean Patent Publications No. 2014-0105887 and 2015-0089650 describe conventional image sensors.

### SUMMARY

Various embodiments of the present invention are directed to an image sensor having improved image sensitivity through increased light condensing efficiency.

Also, various embodiments are directed to an image sensor which is capable of increasing the amount of light absorbed into a photoelectric conversion layer by additionally condensing primarily condensed light, thereby improving sensitivity.

In an embodiment, an image sensor may include: a photoelectric conversion layer; an anti-reflection layer formed over the photoelectric conversion layer so as to minimize reflectance of light; a guide layer formed over the anti-reflection layer, and suitable for guiding the light to the photoelectric conversion layer; and a first condensing layer buried at the inner top of the guide layer, and suitable for condensing incident light.

The image sensor may further include: a color filter layer formed over the guide layer, and suitable for transmitting a specific wavelength of light; and a second condensing layer formed over the color filter layer, and suitable for condensing light incident from outside.

A refractive index of the first condensing layer may be larger than a refractive index of the color filter layer.

The first condensing layer may comprise silicon nitride (Si₃N₄).

The first condensing layer may include a digital microlens of which a side has a single step structure.

The first condensing layer may include a digital microlens of which a side has a double step structure.

The first condensing layer may include a digital microlens of which a side has an inverse double step structure.

The guide layer may comprise at least one of silicon dioxide (SiO₂) and silicon nitride (Si₃N₄).

The first condensing layer may include a digital microlens with a structure having one or more steps, and the digital microlens may have a width and thickness which are determined according to the ratio of the amount of incident light to the amount of light absorbed into a valid region of a desired color pixel and the ratio of the amount of incident light to the amount of light absorbed into a valid region of an undesired color pixel.

In an embodiment, an image sensor may include a microlens suitable for primarily condensing incident light; a color filter formed under the microlens and suitable for transmitting a specific wavelength of light; a digital microlens formed under the color filter and suitable for additionally condensing a specific wavelength of light; a guide layer formed under the color filter, having the digital microlens buried at the inner top thereof, and suitable for guiding the additionally condensed light; an anti-reflection layer formed under the guide layer so as to minimize reflectance of light; and a photo diode formed under the anti-reflection layer and suitable for absorbing light and convert the absorbed light into an electrical signal.

A refractive index of the digital microlens may be larger than a refractive index of the color filter.

The digital microlens may comprise SiN₄, and the guide layer may comprise at least one of SiO₂ and Si₃N₄.

The digital microlens may include one or more of a single-step structure, a double-step structure and an inverse double-step structure.

The digital microlens may have a width and thickness which are determined according to the ratio of the amount of incident light to the amount of light absorbed into a valid region of a desired color pixel and the ratio of the amount of incident light to the amount of light absorbed into a valid region of an undesired color pixel.

### BRIEF DESCRIPTION OF THE DRAWINGS

FIG. 1 is a block diagram illustrating an image sensor, according to an embodiment of the present invention.

FIG. 2 is a plan view illustrating a pixel array, according to an embodiment of the present invention.

FIG. 3 is a side, cross-sectional view illustrating the structure of a pixel, according to an embodiment of the present invention.

FIG. 4 is a side, cross-sectional view illustrating the structure of a pixel, according to another embodiment of the present invention.

FIG. 5 is a side, cross-sectional view illustrating the structure of a pixel, according to yet another embodiment of the present invention.

FIGS. 6A to 6C are diagrams illustrating the structure of digital microlens, according to an embodiment of the present invention.

FIG. 7 is a linear graph illustrating optical characteristics of an image sensor, according to an embodiment of the present invention.

FIGS. 8A to 8C are bar graphs describing optical characteristics of an image sensor, according to an embodiment of the present invention.

FIGS. 9A to 9C are a diagram comparing operational characteristics of a conventional image sensor and an image sensor, according to an embodiment of the present invention.

### DETAILED DESCRIPTION

Various embodiments of the present invention will be described below in more detail with reference to the accompanying drawings. We note, however, that the present invention may be embodied in different forms and should not be construed as being limited to the embodiments set forth herein. Rather, these embodiments are provided so that the disclosure of the invention will be thorough and complete. Throughout the disclosure, like reference numerals refer to like parts throughout the various figures and embodiments of the disclosure.

While the present invention is described detailed descriptions related to publicly known functions or configurations will be ruled out in order not to unnecessarily obscure subject matters of the present invention.

Furthermore, although the terms such as first and second are used herein to describe various elements, these elements should not be limited by these terms, and the terms are used only to distinguish one element from another element.

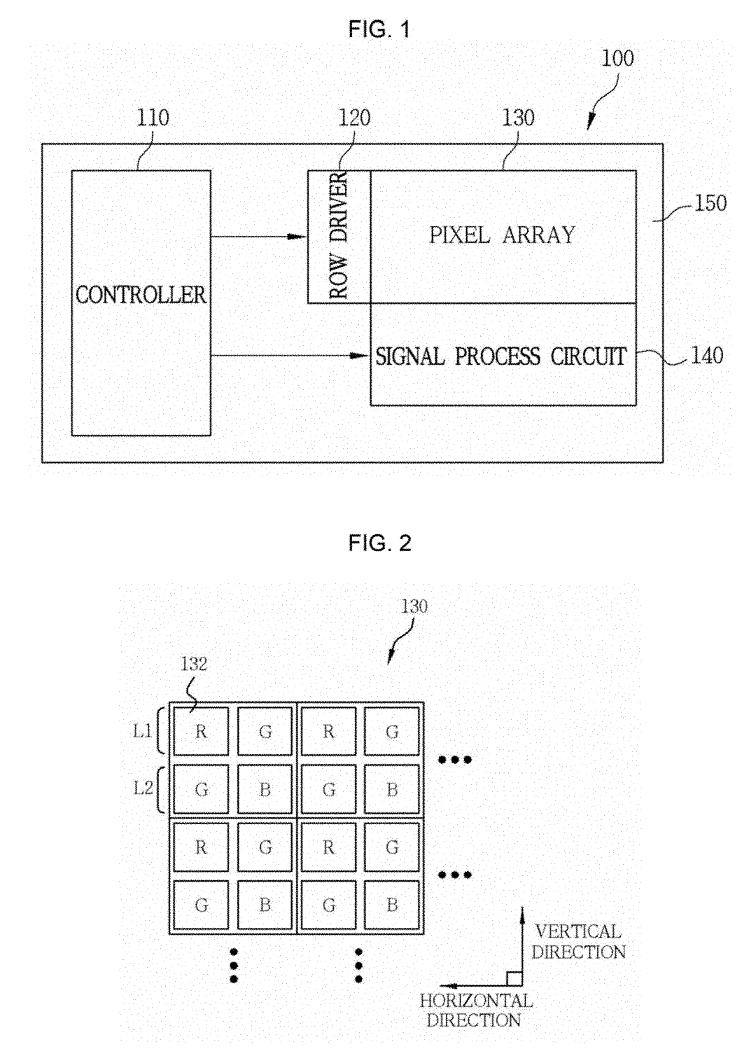

Referring now to FIG. 1 an image sensor 100 is provided, according to an embodiment of the present invention.

According to the embodiment of FIG. 1, the image sensor 100 may include a pixel array 130, a row driver 120, a signal process circuit 140 and a controller 110.

The pixel array 130 may include a plurality of pixels arranged in a matrix shape, each of the pixels including a photoelectric conversion element for photoelectric conversion and a plurality of pixel transistors. The photoelectric conversion element may be or include a photo diode for storing photo charges corresponding to incident light. The pixel transistors may include a transfer transistor to transfer the charges stored in the photoelectric conversion element, a reset transistor to reset the stored charges, a driver transistor to buffer the stored charges, and a select transistor to select a unit pixel.

The row driver 120 may decode a control signal provided from the controller 110 to generate a gate signal for selecting corresponding pixels among the plurality of pixels included in the pixel array 130. For example, the row driver 120 may decode an address signal and provide a gate signal for selecting a row line to the pixel array 130.

The signal process circuit 140 may receive a pixel signal from the pixel array 130 and may convert the received pixel signal into a digital signal. The signal process circuit 140 may include an analog-digital converter for converting a pixel signal into a digital signal and an amplifier for amplifying the digital signal. The analog-digital converter and the amplifier are not illustrated in FIG. 1.

The controller 110 may control the row driver 120 and the signal process circuit 140 in response to a signal inputted from an external device (not shown), and transmit the digital signal outputted from the signal process circuit 140 to an external device, such as, for example, an image display device.

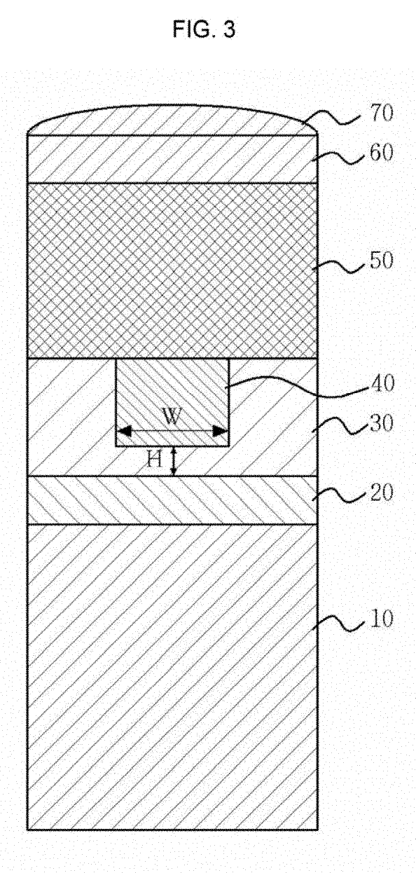

Referring to FIG. 2, a pixel array 130 of FIG. 1, according to an embodiment of the present invention, may include a plurality of pixels 132 which are two-dimensionally arranged in a matrix shape. The pixel array 130 may include red pixels R having a red filter disposed therein, green pixels G having a green filter disposed therein and blue pixels B having a blue filter disposed therein.

For example the pixel array 30 may include a first line L1 in which the red pixels R and the green pixels G are alternately arranged in the horizontal direction and a second line L2 in which the green pixels G and the blue pixels B are alternately arranged in the horizontal direction. The first lines L1 and the second lines L2 may be alternately arranged in the vertical direction.

For another example, in the pixel array 130, the green pixels G of the first line L1 or the green pixels G of the second line L2 may be replaced with white pixels having a white filter disposed therein. In yet another example both the green pixels G of the first line L1 and the green pixels G of the second line L2 may be replaced with white pixels having a white filter disposed therein.

For yet another example, the pixel array 130 may include cyan pixels, magenta pixels and yellow pixels in which cyan filters, magenta filters and yellow filters are respectively disposed.

The pixel array 130 may be divided into an active pixel region including the pixels 132 for converting the incident light into electrical signals and an optical block region surrounding the active pixel region.

The optical block region may be used to block the light incident from outside in order to examine electrical characteristics of the active pixel region. For example, the optical block region may be used to examine a dark noise caused by a dark current, and to prevent the occurrence of the dark noise in the image sensor by compensating for a value corresponding to the dark current.

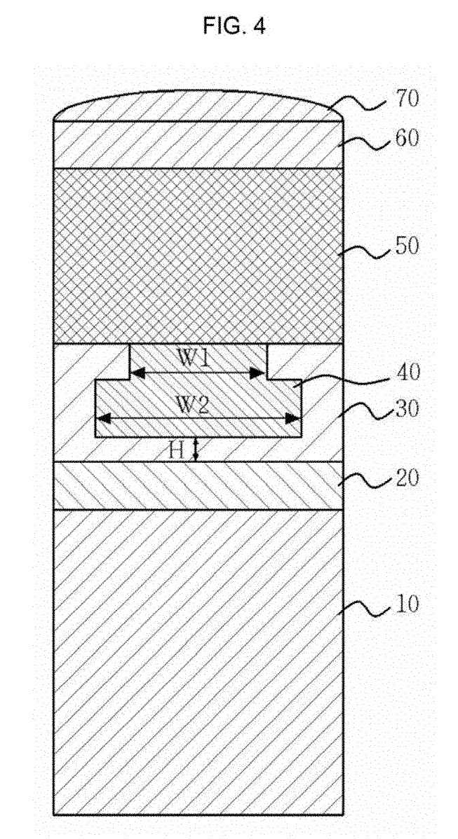

FIG. 3 is a side cross-sectional view illustrating the structure of a pixel 132 of FIG. 2, according to an embodiment of the present invention.

Referring to FIGS. 1 to 3, the image sensor 100 may include the pixel array 130 in which the plurality of pixels 132 are arranged in the matrix shape.

Each of the pixels 132 included in the pixel array 130 may have a structure in which a photoelectric conversion layer 10, an anti-reflection layer 20 a guide layer 30, a first condensing layer 40, a color filter layer 50, a planarization layer 60 and a second condensing layer 70 are sequentially formed from the bottom.

The photoelectric conversion layer 10 may be formed on the semiconductor substrate 150 of FIG. 1, and may include a photoelectric conversion element for absorbing the light penetrating the anti-reflection layer 20 and for storing the charges corresponding to the absorbed light. For example, the photoelectric conversion layer 10 may be formed of silicon (Si). The semiconductor substrate 150 may be in a monocrystalline state and include a silicon-containing material.

The anti-reflection layer 20 may prevent the light focused by the first condensing layer 40 from being reflected from a surface of the photoelectric conversion layer 10. The anti-reflection layer 20 may be formed by applying a dielectric material with a small refractive index onto the surface of the photoelectric conversion layer 10 through a vacuum deposition in order to remove an interference or a scattering caused by reflected light.

The guide layer 30 may be formed over the anti-reflection layer 20. The first condensing layer 40 may be buried at the inner top of the guide layer 30. The guide layer 30 may serve to guide the light focused by the first condensing layer 40 to the photoelectric conversion layer 10. The guide layer 30 may be formed, for example, of at least one of a silicon dioxide (SiO₂) and silicon nitride (Si₃N₄).

The first condensing layer 40 may condense a specific wavelength of the light penetrating the color filter layer 50. The first condensing layer 40 may be comprised of a digital microlens, and may be formed of a medium having a larger refractive index than the color filter layer 50. For example, the first condensing layer 40 may be formed of Si₃N₄.

Since the first condensing layer 40 is formed through a semiconductor process as the photoelectric conversion layer 10, the degree of freedom for design may be improved. For example, the first condensing layer 40 may be or include a digital microlens of which a side has a single-step structure. The digital microlens may have, a width and thickness determined according to the ratio of the amount of incident light to the amount of light absorbed into a valid region of a desired color pixel and the ratio of the amount of incident light to the amount of light absorbed into a valid region of an undesired color pixel. The ratio of the amount of incident light to the amount of light absorbed into a valid region of a desired color pixel may be understood as QE (Quantum Efficiency), and the ratio of the amount of incident light to the amount of light absorbed into a valid region of an undesired color pixel may be understood as crosstalk (X-talk).

The color filter layer 50 may be formed over the guide layer 30. The color filter layer 50 may include a filter for blocking ultraviolet light and infrared light from light incident from outside and for transmitting a specific wavelength of light in, visible light. The color filter layer 50 may include a red, green or blue filter corresponding to the photoelectric conversion layer 10 of a red, green or blue pixel. The color filter layer 50 may be formed of a medium having a smaller refractive index than the first condensing layer 40.

For example, the color filter layer 50 may be implemented with any one of a red filter for transmitting light with a wavelength corresponding to a red color, a green filter for transmitting light with a wavelength corresponding to a green color, and a blue filter for transmitting light with a wavelength corresponding to a blue color. For another example, the color filter layer 50 may be implemented with any one of a cyan filter, a yellow filter and a magenta filter.

The planarization layer 60 may be formed over the color filter layer 50, and applied for planarization of the color filter layer 50

The second condensing layer 70 may be formed over the planarization layer 60 to primarily condense incident light. The second condensing layer 70 may be comprised of a microlens with a radius of curvature. The curvature radius of the microlens may be adjusted in order to improve light condensing efficiency according to the pixel size. For example, the radius of curvature may be adjusted smaller according to the size of the pixels become smaller.

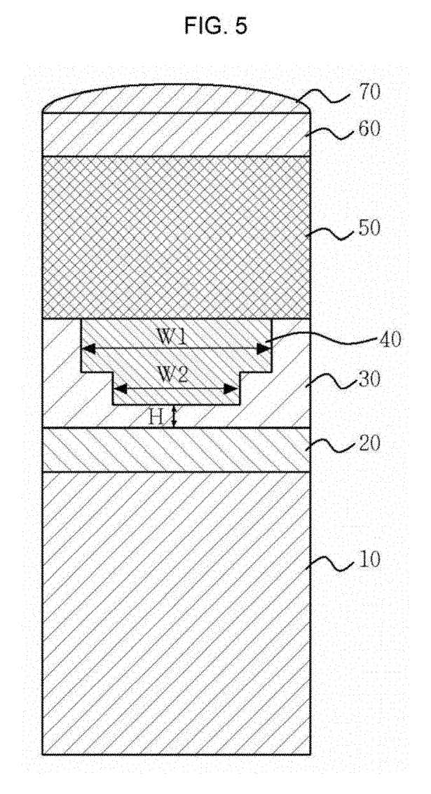

FIG. 4 is a side cross-sectional view illustrating the structure of a pixel of FIG. 2, according to another embodiment of the present invention. In FIG. 4, the descriptions of the same components as those of FIG. 3 will be omitted.

Referring to FIGS. 1 and 4, an image sensor according to the present embodiment may include a pixel array 130. Each pixel 132 of the pixel array 130 may have a structure in which a photoelectric conversion layer 10, an anti-reflection layer 20, a guide layer 30, a first condensing layer 40, a color filter layer 50, a planarization layer 60 and a second condensing layer 70 are sequentially formed from the bottom.

The first condensing layer 40 may be comprised of a digital microlens. The first condensing layer 40 may have a side having a double-step structure. The first condensing layer 40 may be buried at the inner top of the guide layer 30 and may condense a specific wavelength of light penetrating the color filter layer 50. The width and thickness of the first condensing layer 40 having the double-step structure may be determined according to the ratio of the amount of incident light to the amount of a desired wavelength of light absorbed into a valid region of a color pixel and the ratio of the amount of incident light to the amount of an undesired wavelength of light absorbed into a valid region of the color pixel.

The first condensing layer 40 may be formed of a medium having a larger refractive index than the color filter layer 50. For example, the first condensing layer 40 may be formed of Si₃N₄.

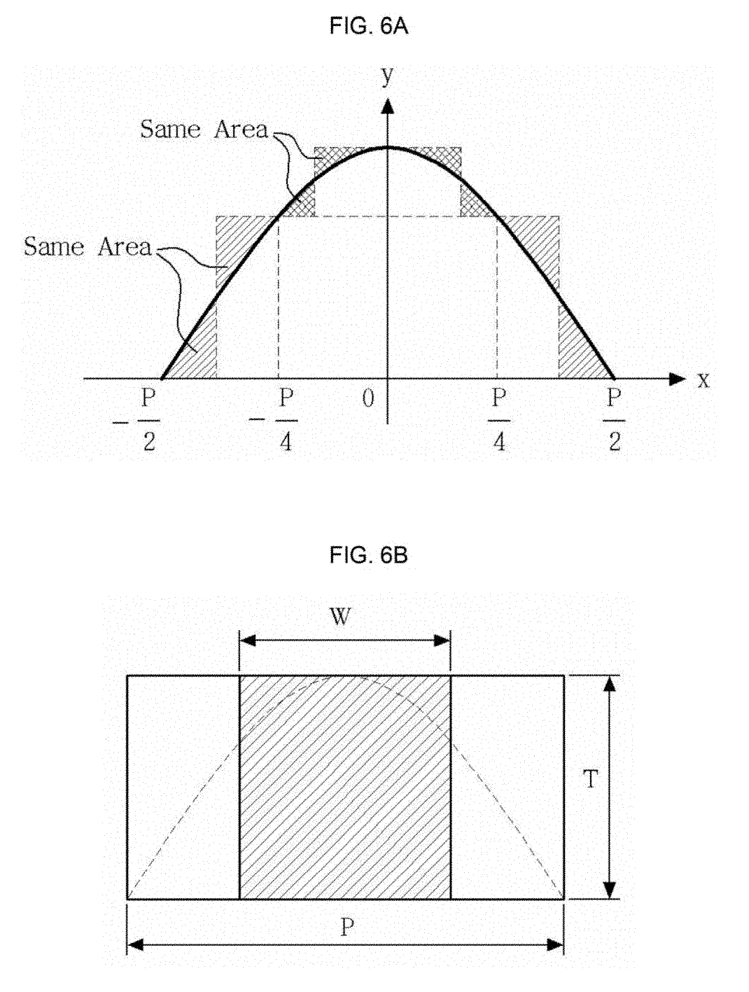

FIG. 5 is a side cross-sectional view illustrating the structure of a pixel of FIG. 2, according to yet another embodiment of the present invention. In FIG. 5, the descriptions of the same components as those of FIG. 3 will be omitted.

Referring to FIGS. 1 and 5, the image sensor according to the present embodiment may include a pixel array 130. Each pixel 132 of the pixel array 130 may have a structure in which a photoelectric conversion layer 10, an anti-reflection layer 20, a guide layer 30, a first condensing layer 40, a color filter layer 50, a planarization layer 60 and a second condensing layer 70 are sequentially formed from the bottom.

The first condensing layer 40 serves as a digital microlens of which a side has an inverse double-step structure. The first condensing layer 40 may be buried at the inner top of the guide layer 30, and may additionally condense a specific wavelength of light penetrating the color filter layer 50. The inverse double-step structure divided to a wide step and a narrower step. The width and thickness of the wide step and the width and thickness of the narrower step may be determined according to the ratio of the amount of incident light to the amount of a desired wavelength of light absorbed into a valid region of a color pixel and the ratio of the amount of incident light to the amount of an undesired wavelength of light absorbed into a valid region of the color pixel.

The operation of the image sensor according to various embodiments of the present invention will be described as follows.

Referring to FIGS. 1 to 5, the second condensing layer 70 may primarily condense the incident light functioning as a microlens with a radius of curvature.

The color filter layer 50 may block ultraviolet light and infrared light from the light focused by the second condensing layer 70, and transmit a specific wavelength of light in visible light. The red filter of a red pixel may transmit light with a wavelength corresponding to a red color. The green filter of a green pixel may transmit light with a wavelength corresponding to a green color. The blue filter of a blue pixel may transmit light with a wavelength corresponding to a blue color.

The first condensing layer 40 may be buried at the inner top of the guide layer 30, and formed of a medium having a larger refractive index than the color filter layer 50. The first condensing layer 40 may form a digital microlens of which a side has a single-step, double-step or inverse double step structure, and condenses a specific wavelength of light penetrating the color filter layer 50. The first condensing layer 40 may increase the amount of light absorbed into a valid region of a desired color pixel with respect to the amount of incident light, thereby improving the light condensing efficiency.

The guide layer 30 may be formed of at least one of SiO₂ and Si₃N₄ to guide light to the photoelectric conversion layer 10, the light being additionally focused by the first condensing layer 40.

The anti-reflection layer 20 may prevent the light focused by the first condensing layer 40 from being reflected from the surface of the photoelectric conversion layer 10 after the light may penetrate the guide layer 30. The anti-reflection layer 20 may remove interference or scattering caused by reflected light.

The photoelectric conversion layer 10 may absorb light penetrating the anti-reflection layer 20, and may store charges corresponding to the absorbed light.

The row driver 120 may decode an address signal provided from the controller 110 to generate a gate signal for selecting corresponding pixels among the plurality of pixels included in the pixel array 130, and to provide the gate signal to the pixel array 130.

The pixel array 130 may provide a pixel signal to the signal process circuit 140, the pixel signal corresponding to the charges stored in a pixel selected by the gate signal.

The signal process circuit 140 may receive the pixel signal from the pixel array 130 to convert the pixel signal into a digital signal, and provide the digital signal to an external host device. The host device may include a digital camera, a camcorder, a mobile terminal, a security camera or a medial micro camera, in which an image sensor to convert an optical image into an electrical signal may be employed.

As such, the image sensor according to embodiments of the present invention may primarily condense incident light through the microlens, and additionally condense a specific wavelength of light penetrating the color filter layer 50 through the first condensing layer 40 buried at the inner top of the guide layer 30. Thus, the image sensor can increase the amount of light absorbed into the photoelectric conversion layer 10, and improve the light condensing efficiency. Therefore, the sensitivity of the image sensor can be improved.

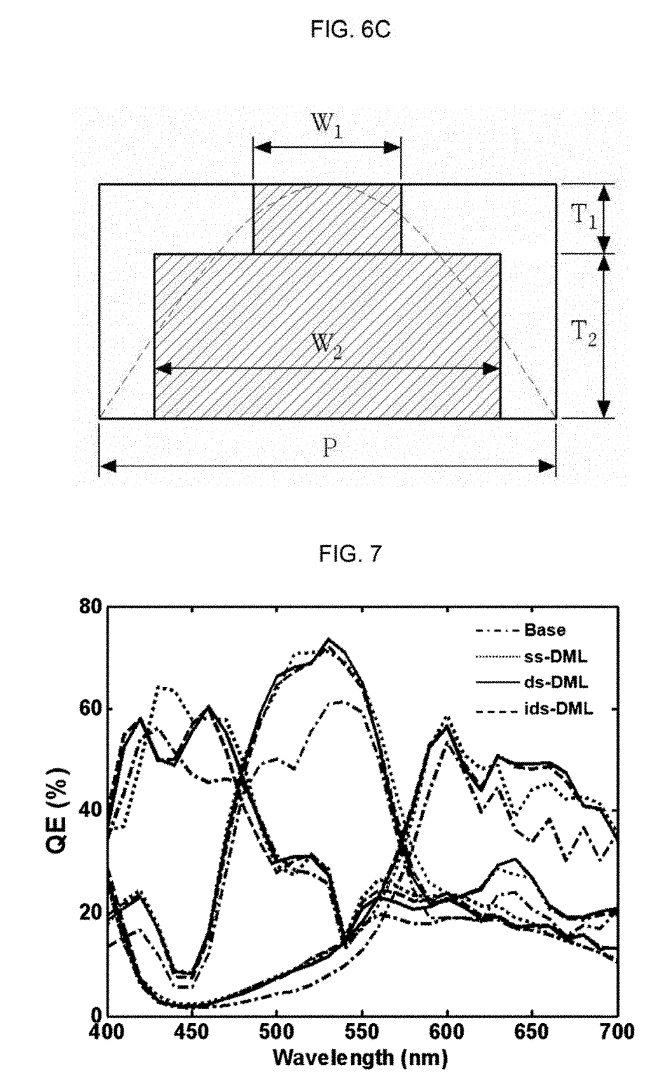

FIG. 6A is diagrams illustrating the microlens having the curvature radius. FIG. 6B is diagrams illustrating the digital microlens having a single step structure. FIG. 6C is diagrams illustrating the digital microlens having a double step structure.

Referring to FIGS. 6A and 6C, the digital microlens may have a width and thickness which are designed according to the pixel size P and the curvature radius, of the microlens. However this is only an example for designing the digital microlens and the present invention is not limited thereto.

The width and thickness of the digital microlens may be determined according to the ratio of the amount of incident light to the amount of a desired wavelength of light absorbed into a valid region of a color pixel and the ratio of the amount of incident light to the amount of an undesired wavelength of light absorbed into a valid region of the color pixel.

An optimized structure of the digital microlens may be found from the test for changing the width and thickness of the first condensing layer 40 relative to the second condensing layer 70 with a specific curvature radius so that the ratio of the amount of incident light to the amount of a desired wavelength of light absorbed into a valid region of a color pixel can be increased.

For example, in the case of the single-step structure illustrated in FIG. 3, the curvature radius of the second condensing layer 70 may be set to 400 nm, the width W of the first condensing layer 40 may be set to 700 nm, the height H between the first condensing layer 40 and the anti-reflection layer 20 may be set to 100 nm. In the case of the double-step structure illustrated in FIG. 4, the curvature radius of the second condensing layer 70 may be set to 450 nm, the width W1 of the narrow step of the first condensing layer 40 may be set to 300 nm, whereas the width W2 of the wider step of the same structure may be set to 700 nm, and the height H between the first condensing layer 40 and the anti-reflection layer 20 may be set to 100 nm. In the case of the inverse double-step structure illustrated in FIG. 5, the curvature radius of the second condensing layer 70 may be set to 450 nm the width W1 of the wider step of the first condensing layer 40 may be set to 700 nm the width W2 of the narrow step of the first condensing layer 40 may be set to 300 nm, and the height H between the first condensing layer 40 and the anti-reflection layer 20 may be set to 100 nm.

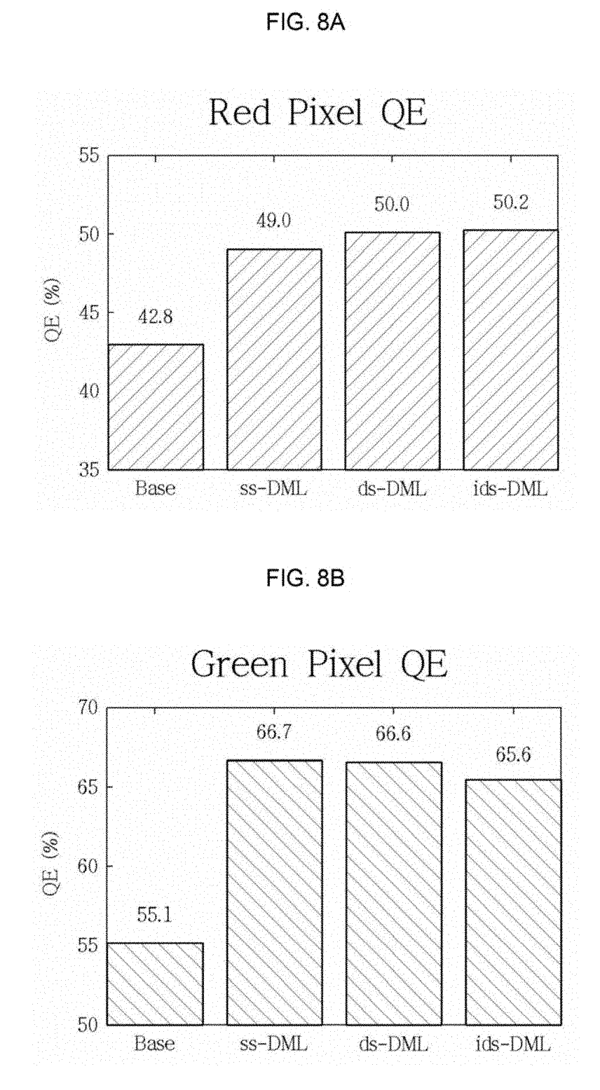

FIG. 7 is a linear graph illustrating the optical characteristics of the image sensor according, to embodiments of the present invention. More specifically FIG. 7 shows the percent QE as a function of incident light wavelength measured in nanometers (nm) for each of four cases, namely, a base case, an ss-DML case including the first condensing layer 40 with the single-step structure of FIG. 3, a ds-DML case including the first condensing layer 40 with the double-step structure of FIG. 4, and an ids-DML including the first condensing layer 40 with the inverse double-step structure of FIG. 5. As shown in FIG. 7, the image sensor ss-DML including the first condensing layer 40 with a single-step structure exhibits high QE for the light having wavelengths corresponding to the blue (about 450 nm) and the green (about 540 nm), and the image sensor ids-DML including the first condensing layer 40 with an inverse double-step structure exhibits high QE for the light having a wavelength corresponding to the red (about 620 nm). The QE represents the ratio of the amount of incident light (IL) to the amount of a desired wavelength of light absorbed (AL) into a valid region of a color pixel, i.e., (IL/AL)*100.

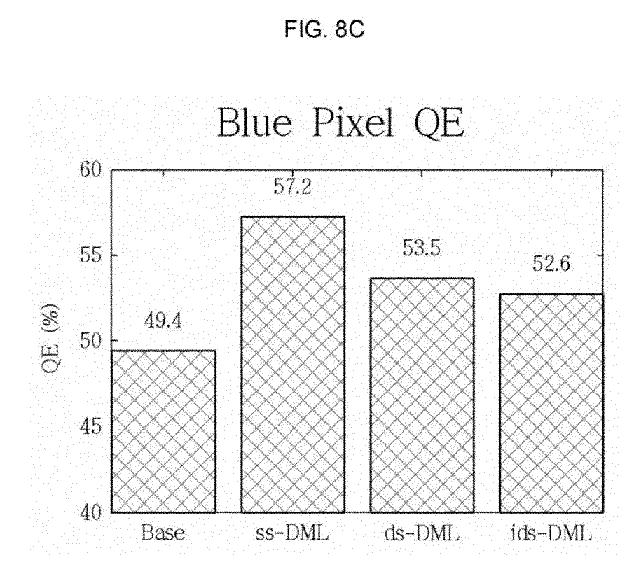

FIGS. 8A to 8C are bar graphs describing optical characteristics of the image sensor according to the aforementioned embodiments of the present invention as compared to a base case. FIG. 8A illustrates red pixel QE, FIG. 8B illustrates green pixel QE, and FIG. 8C illustrates blue pixel QE.

Referring to FIGS. 8A to 8C, the inverse double step structure exhibits the highest QE for the red pixel. The single step structure exhibits the highest QE for the green and blue pixels. The double step structure exhibits higher QE for the red and green pixels.

In the present embodiments, it has been described that the first condensing layer 40 has the single-step, the double-step or inverse double-step structure. However, the present invention is not limited thereto. However, when the number of steps is further increased, the light condensing ability will not be changed.

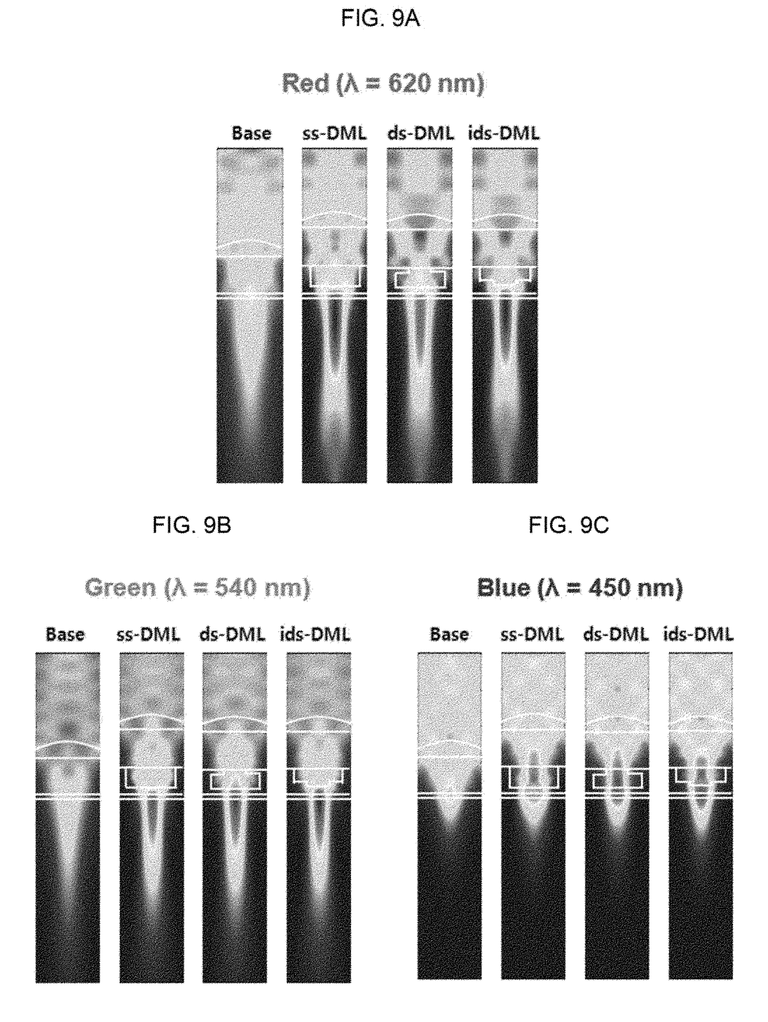

FIGS. 9A to 9C are a diagram for comparing the operation characteristics of the conventional image sensor (base) and the image sensor according to the aforementioned embodiments of the present invention. FIG. 9A is diagram for illustrating the optical characteristics of the red pixel. FIG. 9B is diagram for illustrating the optical characteristics of the green pixel. FIG. 9A is diagram for illustrating the optical characteristics of the blue pixel.

Referring to FIGS. 9A to 9C, the image sensor according to the aforementioned embodiments of the present invention can more precisely condense light having a wavelength corresponding to red, green or blue to one spot, compared to the conventional image sensor, the inverse double-step structure ids-DML can more efficiently condense light having a wavelength corresponding to red. Referring to the single-step structure ss-DML can more efficiently condense light having a wavelength corresponding to green and blue, the double-step structure ds-DML can more efficiently condense light having a wavelength corresponding to red and green. The image sensor including the first condensing layer 40 with the single-step double-step or inverse double-step structure can more efficiently condense light having a wavelength corresponding to red, green or blue, compared to the conventional image sensor. As such, the light condensing characteristics of the image sensor according to the present embodiments can be significantly improved, compared to the conventional image sensor.

Since the image sensor according to the embodiments of the present invention additionally condenses the primarily focused light, the amount of light absorbed into the photoelectric conversion layer 10 can be increased, causing the light condensing efficiency to be improved. Thus, the sensitivity of the image sensor can be improved.

Furthermore, since the guide layer 30 and the first condensing layer 40 are formed through a semiconductor process, the degree of design freedom can be improved, and the focus adjustment can be easily performed.

Furthermore, since the thickness and width of the first condensing layer having a step structure can be set according to QE and X-talk, the optimized structure can be designed for each color pixel.

Although various embodiments have been described for illustrative purposes, it will be apparent to those skilled in the art that various changes and modifications may be made without departing from the spirit and scope of the invention as defined in the following claims.

1. An image sensor comprising:
a photoelectric conversion layer;
an anti-reflection layer formed over the photoelectric conversion layer so as to minimize reflectance of light;
a guide layer formed over the anti-reflection layer, the guide layer being suitable for guiding the light to the photoelectric conversion layer; and
a first condensing layer buried at an uppermost portion of the guide layer to be exposed at a top surface of the guide layer and surrounded by the guide layer, the first condensing layer being suitable for condensing incident light,
wherein the first condensing layer comprises an upper layer and a lower layer, widths and thicknesses of the upper layer and the lower layer are determined according to a ratio of an amount of the incident light to an amount of a desired wavelength of light absorbed into a valid region of a color pixel and a ratio of the amount of the incident light to an amount of an undesired wavelength of light absorbed into the valid region of the color pixel, and the lower layer has greater width and thickness than the upper layer.

2. The image sensor of claim 1, further comprising:
a color filter layer formed over the guide layer, and suitable for transmitting a specific wavelength of the light; and
a second condensing layer formed over the color filter layer, and suitable for condensing the light incident from outside.

3. The image sensor of claim 2, wherein a refractive index of the first condensing layer is a larger than a refractive index of the color filter layer.

4. The image sensor of claim 2, further comprising a planarization layer formed between the color filter layer and the second condensing layer, and applied for planarization of the color filter layer.

5. The image sensor of claim 1, wherein the first condensing layer comprises silicon nitride (Si₃N₄).

6-8. (canceled)

9. The image sensor of claim 1, wherein the guide layer comprises at least one of silicon dioxide (SiO₂) and silicon nitride (Si₃N₄).

10. (canceled)

11. An image sensor comprising:
a microlens suitable for primarily condensing incident light;
a color filter formed under the microlens and suitable for transmitting a specific wavelength of the incident light;
a digital microlens formed under the color filter and suitable for additionally condensing the specific wavelength of the incident light;
a guide layer formed under the color filter, and suitable for guiding the additionally condensed light;
an anti-reflection layer formed under the guide layer so as to minimize a reflectance of the incident light; and
a photo diode formed under the anti-reflection layer and suitable for absorbing the guided light and converting the absorbed light into an electrical signal,
wherein the digital microlens is buried at an uppermost portion of the guide layer to be exposed at a top surface of the guide layer and surrounded by the guide layer,
wherein the digital microlens comprises an upper layer and a lower layer, widths and thicknesses of the upper layer and the lower layer are determined according to a ratio of an amount of the incident light to an amount of a desired wavelength of light absorbed into a valid region of a color pixel and a ratio of the amount of the incident light to an amount of an undesired wavelength of light absorbed into the valid region of the color pixel, and the lower layer has greater width and thickness than the upper layer.

12. The image sensor of claim 11, wherein a refractive index of the digital microlens is larger than a refractive index of the color filter.

13. The image sensor of claim 11, wherein the digital microlens comprises Si₃N₄, and
the guide layer comprises at least one of SiO₂ and Si₃N₄.

14-15. (canceled)

16. The image sensor of claim 1, wherein the first condensing layer and the photoelectric conversion layer are formed through a semiconductor process.

17. The image sensor of claim 11, wherein the digital microlens and the photo diode are formed through a semiconductor process.
